(19) United States
(12) Patent Application Publication
(10) Pub. No.: US 2009/0199903 A1
(43) Pub. Date: Aug. 13, 2009

(54) ORGANIC SOLAR CELL

(75) Inventors: Takahito Oyamada, Saitama (JP); Chihaya Adachi, Fukuoka (JP)

Correspondence Address: SUGHRUE MION, PLLC, 2100 PENNSYLVANIA AVENUE, N.W., SUITE 800, WASHINGTON, DC, 20037, US

(73) Assignees: Takahito OYAMADA, Tsurugashima-shi , Saitama (JP); Chihaya ADACHI, Fukuoka-shi ,Fukuoka (JP); PIONEER CORPORATION, Meguro-ku , Tokyo (JP)

(21) Appl. No.: 12/307,009

(22) PCT Filed: May 31, 2007
(86) PCT No.: PCT/JP2007/061094

§ 371 Date: Dec. 30, 2008

(30) Foreign Application Priority Data
Jun. 30, 2006 (JP) 2006-181713

(51) Int. Cl. H01L 31/0256

(52) U.S. Cl. 136/263; 257/E31.003

(57) ABSTRACT

To provide an organic solar cell in which a light is preferably introduced from a side opposite to a substrate and the light thus introduced can be efficiently used.

The organic solar cell including a substrate; a first electrode; an organic solid layer; and a second electrode, laminated in this order, wherein the second electrode is made from an alloy containing magnesium and has a thickness of 1 to 20 nm.

### TECHNICAL FIELD

The present invention relates to a technical field of an organic solar cell formed by laminating a substrate, a first electrode, a second electrode.

### BACKGROUND ART

In recent years, energy consumption drastically increases along with industrial development. Under such the situation, it is required to develop a new and clean energy source having an economical efficiency and a high performance and without causing burden to the global environment. A solar cell is paid attention to out of those prospected as the new energy source since it utilizes inexhaustible sunlight. The solar cell is structured to laminate a substrate, a first electrode (anode), an organic solid layer, and a second electrode (cathode). In the solar cell thus structured, it is ordinary to make light incident on a side of the substrate. For this, it is necessary to use a transparent substrate and a transparent electrode respectively for the substrate and the anode. Specifically, there has been used a glass or the like as the transparent substrate and an indium oxide such as ITO and IZO or the like has been used as the transparent electrode. However, since it is necessary to select a trans parent material as the substrate and the anode, there is a problem that there is a limited option in selecting the material. Further, a thickness of 30 to 500 nm at the minimum is required in reducing a sheet resistance and increasing conductivity. However, there occur a problem that a part of incident light is locked inside the transparent electrode and further the transparent substrate when such the relatively thick transparent electrode is used, thereby lowering efficiency of using the light, as disclosed in Patent Document 1. Patent Document 1: Japanese Unexamined Patent Publication No. H9-74216.

### DISCLOSURE OF INVENTION

### Problem that the Invention is to Solve

In order to solve the above problem, it is developed to receive a light from a side opposite to the substrate. As such in a case where the light received from the side opposite to the substrate, it is unnecessary to make the substrate and the anode transparent, whereby the option of selecting the material used as the substrate and the anode is not limited. Further, because it is unnecessary to use the above-mentioned material as the anode, it is unnecessary to make the thickness of the anode thicker. By this, there is no problem that the part of the incident light is locked inside the anode and the efficiency of using the light is lowered. Accordingly, it seems as if the above-mentioned problem is solved but the cathode should be transparent and it is necessary to use an indium oxide such as ITO and IZO as the cathode or the like in a case where the light is received from the side opposite to the substrate. In this case, it is necessary to use a relatively thick transparent electrode by the above-mentioned reason, whereby there still occurs the problem that the part of the incident light is locked inside the transparent node and the efficiency of using the incident light is lowered. Further, when the transparent electrode is laminated on an organic solid layer in an ordinary organic device manufacturing process lamination by spattering is ordinarily employed. Therefore, there is a new problem that the organic solid layer laminated under the cathode is spoiled by plasma and damaged at the time.

The present invention is provided in consideration of the above problem, and an object of the present invention to provide an organic solar cell enabling to introduce a light preferably on a side opposite to a substrate and to use the introduced light efficiently.

### Means for Solving the Problem

In order to solve the problem, the invention according to claim 1 is characterized that an organic solar cell including: a substrate; a first electrode; an organic solid layer; and a second electrode, laminated in this order, wherein the second electrode is made from an alloy containing magnesium and has a thickness of 1 to 20 nm.

In order to solve the problem, the invention according to claim 2 is characterized that an organic solar cell including: a substrate; a first electrode; an organic solid layer; and a second electrode, laminated in this order, wherein the second electrode is formed by a plurality of layers, and at least one of the plurality of layers is made from an alloy containing magnesium, and a total thickness of the second electrode is 1 to 20 nm.

### BRIEF EXPLANATION OF DRAWINGS

FIG. 1a A cross-sectional view for schematically showing an example of a mode for carrying out the organic solar cell according to the present invention

FIG. 1b A view showing an auxiliary electrode

FIG. 1c A view showing an auxiliary electrode

FIG. 2 A view showing a relationship between a wavelength and a transmission rate

FIG. 3 A view showing a relationship between a wavelength and a transmission rate

### EXPLANATION OF NUMERICAL REFERENCES

1: SECOND ELECTRODE
2: ORGANIC SOLID LAYER
3: BUFFER LAYER
4: FIRST ELECTRODE
5: SUBSTRATE
6: AUXILIARY ELECTRODE
11: ORGANIC ELECTRON DONOR LAYER
12: ELECTRON RECEPTOR LAYER

Hereinafter, a detailed explanation is given to the organic solar cell according to the present invention.

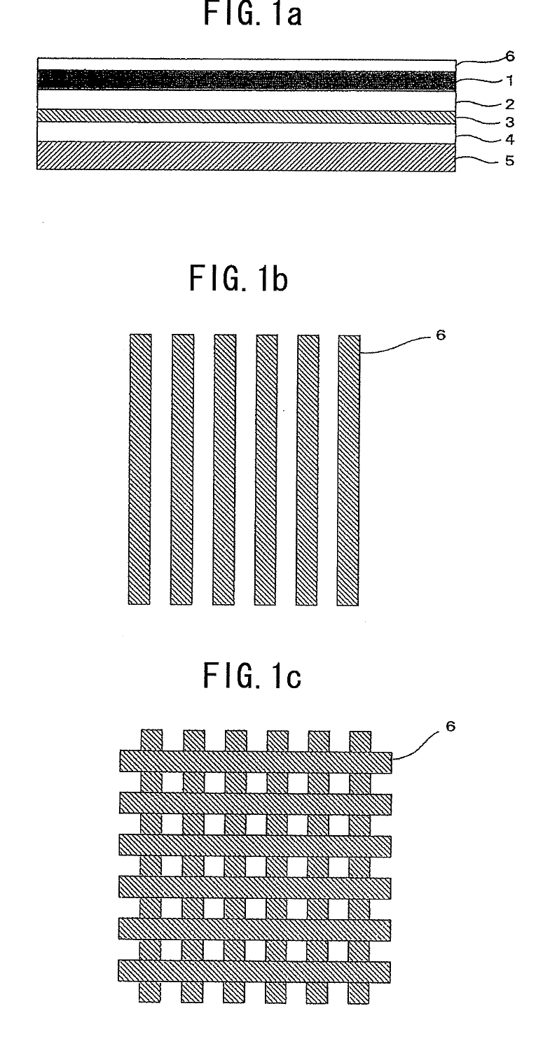

FIG. 1a is a schematic cross-sectional view showing an example of the embodiment of the organic solar cell according to the present invention.

As shown in FIG. 1, the organic solar cell according to the present invention is structured to laminate the substrate 5, the first electrode 4, the organic solid layer 2, and the second electrode 1 in this order. The second electrode 1 in the organic solar cell is made from an alloy containing magnesium and having a thickness of 1 to 20 nm. It is possible to demonstrate an effect of the present invention respectively in cases where the first electrode is an anode electrode and the second electrode is a cathode electrode and where the first electrode is the cathode electrode and the second electrode is the anode electrode. Hereinafter, the case where the first electrode is an anode electrode and the second electrode is a cathode electrode will be described.

### (Second Electrode (Cathode Electrode))

In explaining the second electrode (cathode) forming the organic solar cell according to the present invention, the explanation is given with respect to each case of (I) the second layer (cathode) is formed by a single layer and (II) the second layer (cathode) is formed by a plurality of layers.

(I) The Case where the Second Layer (Cathode) 1 is Formed by a Single Layer

When the cathode 1 is formed by the single layer structure, the cathode 1 is characterized to be formed by an alloy containing magnesium.

Here the alloy containing magnesium is an alloy containing magnesium (Mg) and metals other than magnesium.

Although “a number of magnesium atoms” with respect to “a number of all metal atoms”, namely “atomic ratio of magnesium” is not specifically limited, it is preferable to make it 1 to 90 percents, more preferably 20 to 40 percents.

Further, in metals other than magnesium, it is not specifically limited, and Ag, Cu, Au, In, Sn, Al, Zn, alkali metal, a group II element, a rare metal, a transition metal, or the like may be used. By using these metals, it is possible to form a transparent or semi-transparent cathode. Further, it is preferable to use such the metal because conductivity can be maintained. Especially, it is preferable that a metal other than magnesium is Ag. The alloy formed by magnesium and Ag is effective as the cathode because a carrier can be efficiently pulled out. Further, a metal other than magnesium may be not limited to only a single body described above but also a conductive oxide like ITO (Indium Tin Oxide). Further, it may not be limited to a single type but both of the above Ag and ITO may be used (namely a composite conductive film made from Ag, ITO, and Mg may be used).

Further, there is a characteristic in the organic solar cell according to the present invention that a thickness of the cathode made from such the material is 1 to 20 nm.

By thinning the thickness of the cathode 1 as such, it is possible to prevent a part of solar light from being locked inside the transparent electrode and efficiency of utilizing incident light can be enhanced. Here it is preferable that the thickness of the second electrode (cathode) 1 is 1 to 20 nm, more preferably the thickness of the second electrode (cathode) 1 is 1 to 5 nm.

If the thickness of the cathode 1 is thinned, it is possible to maintain the conductivity good since the cathode 1 is made from the alloy containing magnesium as described above.

The cathode 1 may be formed by methods such as a vacuum deposition method (resistance heating evaporation method), a vacuum deposition method (electron beam deposition method), a paint coating method. As such since the cathode 1 can be laminated on the organic solid layer 2 without using the spattering method or the like, which is conventionally used in laminating the cathode on the organic solid layer, the organic solid layer 2 is scarcely spoiled by plasma or the like and scarcely damaged at the time of laminating the cathode 1.

(II) The Case where the Second Layer (Cathode) 1 is Formed by the Plurality of Layers

In the present invention, it is possible to make the cathode to have a plural layer structure but not a single layer structure. In a case where the cathode is structured by a plurality of layers, at least one of the layers is characterized to be made from the alloy containing magnesium.

In this, because the layer made from the alloy containing magnesium is similar to the alloy containing magnesium described above, description thereof is omitted.

The layer other than the layer made from the alloy containing magnesium is not specifically limited, and may be formed by Ag, Cu, Au, In, Sn, Al, Zn, alkali metal, a group II element, a rare metal, a transition metal, or the like. In this it is preferable that at least one layer other than the layer made from the alloy containing magnesium is the layer made from Ag. By this it is possible to efficiently pull out a carrier. Further, when the cathode 1 is not made from the alloy containing magnesium but from only Ag, it is not possible to simultaneously satisfy both the transparency and the conductivity (in a case where the cathode 1 is made thin, the conductivity is deteriorated and no electric current flows, on the other hand in a case where the cathode 1 is made thick enough to enable to flow through the cathode 1, the transparency is deteriorated). As such in a case where the cathode is formed by a plurality of layers, a positional relationship between a layer made from the alloy containing magnesium inside the cathode 1 and the layer made from an alloy other than the alloy containing magnesium is such that the layer made from the alloy other than the alloy containing magnesium is arranged at a position in contact with the organic solid layer 2.

Further, in a case where the cathode 1 is formed by a plurality of layers, it is characterized in that a total thickness of cathode is 1 to 20 nm. By making the thickness of the cathode 1 thus thin, it is possible to prevent a part of sunlight from being locked inside the transparent electrode and an efficiency of using the incident light can be enhanced. Further, by making the total thickness of cathode 1 to 5 nm, the transparency can be secured 80% or more.

Even in a case where the cathode 1 is formed by plural layers containing the alloy layer containing magnesium, the method of forming the same can be a vacuum deposition method (resistance heating evaporation method), a vacuum deposition method (electron beam deposition method), a paint coating method, or the like in a manner similar to the above (I).

### (Organic Solid Layer)

Next the organic solid layer 2 will be described.

The organic solid layer 2 is fabricated by at least an organic electron receptor layer 11 and an electron receptor layer 12.

An organic electron receptor body forming the organic electron receptor layer (hereinafter it may be referred to as “p-type layer”) 11 is not specifically limited as long as its electronic charge carrier is a positron and a material thereof shows a p-type semiconductor property.

Specifically, there may be used high molecules like an oligomer or polymer having thiophene and its derivative as a skeleton, an oligomer or polymer having phenylenevinylene and its derivative as a skeleton, an oligomer or polymer having thienylenevinylene and its derivative as a skeleton, an oligomer or polymer having vinylcarbazole and its derivative as a skeleton, an oligomer or polymer having pyrrole and its derivative as a skeleton, an oligomer or polymer having pyrrole and its derivative as a skeleton, an oligomer or polymer having acetylene and its derivative as a skeleton, an oligomer or polymer having isothianaphene and its derivative as a skeleton, an oligomer or polymer having heptadiene and its derivative as a skeleton, and

low molecules such as metal-free phthalocyanines, metal phthalocyanines, and their derivative; diamines; phenyldiamines and their derivatives; acenes such as pentacene and their derivatives; a metal-free porphyrin such as porphyrin, tetramethylporphyrin, tetraphenylporphyrin, diazotetrabenzporphyrin, monoazotetrabenzporphyrin, diazotetrabenzporphyrin, triazotetrabenzporphyrin, octaethylporphyrin, oktaalkylthioporphyrazine, oktaalkylaminoporphyrazine, hemiporphyrazine, chlorophyll, a metal porphyrin and their derivatives; a cyanine dye; a merocya; a quinone dye such as benzoquinone and naphthoquinone.

As a central metal of metal phthalocyanine and metal porphyrin, there are used metals such as magnesium, zinc, copper, silver, aluminum, silicon, titanium, vanadium, chromium, manganese, iron, cobalt, nickel, stannum, platinum, and lead, a metal oxide, and a metal halogenide. Especially, an organic material having its absorption band in a visible light range (300 to 900 nm) is preferable.

On the other hand, as an electron receptor body forming the electron receptor layer (hereinafter it may be referred to as “n-type layer”) 12, it is not specifically limited as long as its electronic charge carrier is an electron and a material thereof shows a property of n-type semiconductor.

Specifically, as the organic electron receptor, there are used high moleculers such as an oligomer or polymer, an oligomer or polymer having quinoline and its derivative as a skeleton, a ladder polymer of benzophenanthrolines and their derivatives, and cyanopolyphenylenevinylene; and

low moleculars such as a fluorinated metal-free phthalocyanine, fluorinated metal Phthalocyanines and their derivatives, perylene and its derivative, naphthalene derivative, and bathocuproine and its derivative. Further, modified and unmodified fullerenes, carbon nano tubes and so on can be mentioned. In a manner similar to the above cases, an organic material having an absorption band in the visible light range (300 to 900 nm) is desirable.

Although a positional relationship of laminating the organic solid layer 2 (p-type layer 11 and n-type layer 12) is not specifically limited, it is preferable to arrange the p-type layer on a side of the anode 4 and the n-type layer on a side of the cathode. Further, it is possible to arrange the n-type layer on the side of the anode 4 and the p-type layer on the side of the cathode by arranging MoOx on the side of the cathode 1. Further, it is possible to laminate a co-deposite layer (i-type layer) obtained by co-depositing the p-type layer and the n-type layer, not single layers of the p-type layer and the n-type layer. When laminating this co-deposite layer, a positional relationship thereof may be, from the side of the anode 4, an order of the p-type layer, the i-type layer, and the n-type layer or an order of the n-type layer, the i-type layer, and the p-type layer. Or it may be a single layer (I-layer) obtained by co-depositing a p-type material and a n-type material. In the case of a paint type, it is possible to mix the p-type material and the n-type material to thereby form a film.

### (First Electrode (Cathode))

Next the anode 4 is described.

The anode 4 is the electrode for efficiently collecting the positrons generated between the anode 4 and the cathode 1. It is preferable to use an electrode material made from a metal, an alloy, an electric conductive compound and a mixture thereof having a high work function of 4 eV or more. Such the electrode materials may be an electrode material ordinarily used as an anode of solar cell. For example, the material having both electric conductivity and transparency such as ITO (indium tin oxide), SnO₂, AZO, IZO, and GZO can be mentioned. Since the conventional solar cell is structure to receive light from a side of substrate, the transparency is required in the anode and therefore the above-mentioned material has been used. Since the present invention is structured to receive the light on a side opposite to the substrate, it is sufficient that the anode is conductive and the transparency is unnecessary. Therefore, it is possible to use for example Ag, Cu, Au, In, Sn, Al, Zn, alkali metal, a group II element, a rare metal, a transition metal, or the like. Because it is unnecessary to select the material having the transparency, an option of selecting the material used as the anode expands. Especially, an incident light can be effectively used by using the electrode material without transparency as the anode.

Further, the electric material used as the anode is preferably a material having reflectiveness. If it is possible to reflect a light by the anode when receiving the light on the side opposite to the cathode 5, it is possible to efficiently collect positron generated between the anode 4 and the cathode 1. As such the electrode material, for example metal such as Ag, Al, and Au and an alloy such as MgAg and MgAu can be mentioned. In a case where metal such as Ag is used as the anode, it is preferable to insert Cr, Ti, Mg or the like between the substrate 5 and the anode 4 to improve a contact with the substrate 5. The thickness is preferably 0.1 to 10 nm, especially the insertion is preferably by about 1 nm. On the other hand, in a case where the alloy such as MgAg is used, because the contact is good, it is unnecessary to insert Cr or the like between the substrate and the anode 4 as described above. Further, a case where the MgAg alloy is used as the anode 4 is preferable because a reflectance is as good as around 100% and conductivity is maintained.

The thickness of the anode 4 is preferably 20 to 1000 nm, more preferably 20 to 200 nm.

Such the anode 4 can be formed by methods like a vacuum deposition method (resistance heating evaporation method), a vacuum deposition method (electron beam deposition method), a vacuum deposition method (sputtering method), and a paint coating method.

In the organic solar cell according to the present invention, a buffer layer 3 may be formed so as to be in contact with the anode 4 described above (upper or lower of the anode). FIG. 1a shows a case where the buffer layer 3 is formed on the anode 4. Here the buffer layer 3 makes it easy to efficiently pull out carriers to thereby assist the anode

The buffer layer 3 is not specifically limited and there may be used for example oxides such as ITO, IZO, InOₓ, SnOₓ, V₂O₅, Mb₂O₅, TiOₓ, ReOₓ, and MoOₓ and a very thin film (about 1 nm) of Au (work function: about 5.0 eV) and Pt (work function: about 5.3 eV). Especially, it is preferable to use MoOx having a high transparency (transmittance of about 99% when the thickness is 5.5 nm) as the buffer layer. In the case where MoOx is used as the buffer layer, the thickness of MoOx is preferably 1 to 7.5 nm, more preferably 5.5 nm.

The buffer layer 3 may be formed by methods like a vacuum deposition method (resistance heating evaporation method), and a vacuum deposition method (electron beam deposition method).

### (Substrate)

Next, the substrate 5 will be described.

A material and thickness of the substrate 5 are not limited as long as the anode 4 can be formed on a surface thereof. For this, the substrate may be in a sheet-like shape and a film-like shape. The material may be a metal such as glass, aluminum, and stainless, alloys, and a plastic such as polycarbonate and polyester. The present invention is an invention to receive a light on the side opposite to the substrate. Therefore, the transparency of the substrate 5 is unnecessary. Accordingly, it is unnecessary to select the material having transparency and an option of selecting the material used as the substrate is widened.

Here it is preferable that the substrate 5 is as plan as possible. For example, the thickness of the cathode 1 used in the present invention is very thin and about 1 to 20 nm. Therefore, if a height difference is 5 nm or more, there is a possibility that the cathode 1 is cut off. Such the flat substrate is a metal such as Si, glass, aluminum, and stainless, alloys, and a plastic such as polycarbonate and polyester. Further, it may be a substrate formed by laminating Si and SiO₂. Further, in order to maintain flatness of the substrate 5, it is possible to provide physical polishing (plasma etching, ashing or the like), chemical polishing (etching with fluorine, hydrochloric acid, sulfuric acid or the like), coat of a planarizing film, or the like.

### (Auxiliary Electrode)

Next, the auxiliary electrode 6 will be explained.

The auxiliary electrode 6 is formed to lower a resistance of the cathode containing the alloy containing magnesium, namely to further gain an electric current. Specifically, it is prospected that its resistance is high because a film thickness of the cathode is thin. Therefore, in order to lower the resistance of the cathode and gain more electric current, the auxiliary electrode 6 shall be formed in contact with the cathode (in an upper or lower side of the cathode). FIG. 1a shows a case where the auxiliary electrode 6 is formed on the cathode 1. Although a wiring shape of the auxiliary electrode is not specifically limited, it is preferably a grid-like or linear shape so as to prevent a function of pulling in quasi sunlight into the cathode as shown in FIGS. 1b and 1c. A film thickness of the auxiliary electrode 6 is preferably 40 nm to 5000 nm, more preferably 60 nm to 1000 nm. A width of the auxiliary electrode 6 (opening between the auxiliary electrodes) may change depending on a size of the device. An open area ratio, i.e. (an area of a part which causes photoelectric transfer upon absorption of light except for the auxiliary electrode) divided by (the area of a part which causes photoelectric transfer upon absorption of light except for the auxiliary electrode plus a total device area represented by an area of the auxiliary electrode), is preferably 50% or more, more preferably 80% or more. Further, the electrode material of the auxiliary electrode 6 is not specifically limited, preferable a noble metal of Cu, Ag and Au, a transition metal such as Al, Zn, In and Sn, a group II element such as Mg and Ca, an alkali metal such as Cs and Li, and a rare metal such as Y and Yb, wherein a single metal, an alloy and a composite film are used. The auxiliary electrode 6 may be formed by a vacuum deposition (resistance heating), a vacuum deposition (electron gun), and a coating method.

As described, there has been described a case where the first electrode is the anode and the second electrode is the cathode. However, the effect of the present invention can be demonstrated in a case where the first electrode is the cathode and the second electrode is the anode. The layer structure of this case is the substrate 5, the first electrode (cathode) 4, the organic solid layer 2, and the second electrode (anode) 1 as shown in FIG. 1. Explanation of the layers are as described above.

### EMBODIMENT

### Example 1

There was manufactured a cathode of Example 1, i.e. an alloy containing magnesium (a thickness of 5.0 nm) having a ratio of magnesium (Mg) and silver (Ag) being 1:10.

### Example 2

There was manufactured a cathode of Example 2, i.e. an alloy containing magnesium (a thickness of 7.5 nm) having a ratio of magnesium (Mg) and silver (Ag) being 1:10.

### Example 3

There was manufactured a cathode of Example 3, i.e. an alloy containing magnesium (a thickness of 10.0 nm) having a ratio of magnesium (Mg) and silver (Ag) being 1:10.

### Example 4

There was manufactured a cathode of Example 4 (a total thickness of layer being 2.5 nm) formed by silver (Ag) (a thickness of 0.5 nm) and an alloy containing magnesium (a thickness of 2.0 nm) having a ratio of magnesium (Mg) and silver (Ag) being 1:10.

### Example 5

There was manufactured a cathode of Example 5 (a total thickness of layer being 3.7 nm) formed by silver (Ag) (a thickness of 0.7 nm) and an alloy containing magnesium (a thickness of 3.0 nm) having a ratio of magnesium (Mg) and silver (Ag) being 1:10.

### Example 6

There was manufactured a cathode of Example 6 (a total thickness of layer being 5.0 nm) formed by silver (Ag) (a thickness of 1.0 nm) and an alloy containing magnesium (a thickness of 4.0 nm) having a ratio of magnesium (Mg) and silver (Ag) being 1:10.

### Example 7

There was manufactured a cathode of Example 7 formed by silver (Ag) (a thickness of 2.0 nm) and an alloy containing magnesium (a thickness of 8.0 nm) having a ratio of magnesium (Mg) and silver (Ag) being 1:10.

### Comparative Example 1

There was manufactured a cathode of Comparative Example 1, i.e. silver (Ag) having a thickness of 5.0 nm.

### Example 8

There was manufactured an anode of Example 8, i.e. an alloy containing magnesium (a thickness of 60.0 nm) having a ratio of magnesium (Mg) and silver (Ag) being 1:10.

### Example 9

There was manufactured an anode of Example 9, i.e. silver (Ag) having a thickness of 60 nm.

### Example 10

There was manufactured an anode of Example 10, i.e. aluminum (Al) having a thickness of 60 nm.

### Example 11

There was manufactured an anode according to Example 11, i.e. an alloy containing magnesium (MgAu) (a thickness of 60.0 nm) having a ratio of magnesium (Mg) and silver (Ag) being 1:10.

### Example 12

There was formed an anode of an alloy containing magnesium (MgAu) (a thickness of 60.0 nm) having a ratio of magnesium (Mg) and gold (Au) being 1:1 on a substrate. Further, MoO₃ (a thickness of 5.5 nm) as a buffer layer and CuPc (a thickness of 40 nm), C₆₀ (a thickness of 30 nm) and BCP (a thickness of 10 nm) are laminated in this order thereon. Thereafter, a cathode (a total layer thickness of 5.0 nm) formed by laminating silver (Ag) (a thickness of 1.0 nm) as a cathode and an alloy containing magnesium (a thickness of 4.0 nm) having a ratio of magnesium (Mg) and silver (Ag) being 1:10. Thus an organic solar cell according to Example 12 is manufactured.

### Example 13

There was manufactured an organic solar cell according to Example 13 in a manner similar to that of Example 12 other than a condition that silver (Ag) (a thickness of 0.7 nm) and a cathode (a total layer thickness of 3.7 nm) of an alloy containing magnesium (MgAg) (a thickness of 3.0 nm) having a ratio of magnesium (Mg) and silver (Ag) being 1:10 are laminated instead.

### Example 14

There was manufactured an organic solar cell according to Example 14 in a manner similar to that in Example 12 other than a condition that silver (Ag) (a thickness of 0.5 nm) and a cathode (a total layer thickness of 2.5 nm) of an alloy containing magnesium (MgAg) (a thickness of 2.0 nm) having a ratio of magnesium (Mg) and silver (Ag) being 1:10 are laminated instead.

### Example 15

There was manufactured an organic solar cell according to Example 15 in a manner similar to that in Example 12 other than a condition that an anode of an alloy containing magnesium (MgAg) (a thickness of 60 nm) having a ratio of magnesium (Mg) and silver (Ag) being 1:10 are formed instead.

### Example 16

There was manufactured an organic solar cell according to Example 16 in a manner similar to that in Example 12 other than a condition that an organic solid layer is formed without providing a buffer layer on the anode instead.

### Example 17

There was manufactured an organic solar cell according to Example 17 in a manner similar to that in Example 12 of manufacturing the organic solar cell other than a condition that MoO₃ having a thickness of 1.50 nm is formed as a buffer layer instead.

### Example 18

There was manufactured an organic solar cell according to Example 18 in a manner similar to that in Example 12 of manufacturing the organic solar cell other than a condition that MoO₃ having a thickness of 2.50 nm is formed as a buffer layer instead.

### Example 19

There was manufactured an organic solar cell according to Example 19 in a manner similar to that in Example 12 of manufacturing the organic solar cell other than a condition that MoO₃ having a thickness of 3.50 nm is formed as a buffer layer instead.

### Example 20

There was manufactured an organic solar cell according to Example 20 in a manner similar to that in Example 12 of manufacturing the organic solar cell other than a condition that MoO₃ having a thickness of 4.50 nm is formed as a buffer layer instead.

### Example 21

There was manufactured an organic solar cell according to Example 21 in a manner similar to that in Example 12 of manufacturing the organic solar cell other than a condition that MoO₃ having a thickness of 5.50 nm is formed as a buffer layer instead.

### Example 22

There was manufactured an organic solar cell according to Example 22 in a manner similar to that in Example 12 of manufacturing the organic solar cell other than a condition that MoO₃ having a thickness of 6.50 nm is formed as a buffer layer instead.

### Example 23

There was manufactured an organic solar cell according to Example 23 in a manner similar to that in Example 12 of manufacturing the organic solar cell other than a condition that MoO₃ having a thickness of 7.50 nm is formed as a buffer layer instead.

### Example 24

There was manufactured an organic solar cell according to Example 24 in a manner similar to that in Example 12 of manufacturing the organic solar cell other than a condition that CuPc (a thickness of 40 nm), C₆₀ (a thickness of 30 nm) and a mixture material (a thickness of 10 nm) of Cs and BCP having a ratio of Cs and BCP being 1:1 are laminated in this order as the organic solid layer.

### Example 25

There was manufactured an organic solar cell according to Example 25 in a manner similar to that in Example 12 of manufacturing the organic solar cell other than a condition that CuPc (a thickness of 40 nm), C₆₀ (a thickness of 30 nm) and a mixture material (a thickness of 20 nm) of Cs and BCP having a ratio of Cs and BCP being 1:1 are laminated in this order as the organic solid layer.

### Example 26

There was manufactured an organic solar cell according to Example 26 in a manner similar to that in Example 12 of manufacturing the organic solar cell other than a condition that CuPc (a thickness of 40 nm), C₆₀ (a thickness of 30 nm) and a mixture material (a thickness of 30 nm) of Cs and BCP having a ratio of Cs and BCP being 1:1 are laminated in this order as the organic solid layer.

### Example 27

There was manufactured an organic solar cell according to Example 27 in a manner similar to that in Example 12 of manufacturing the organic solar cell other than a condition that CuPc (a thickness of 40 nm), C₆₀ (a thickness of 30 nm) and a mixture material (a thickness of 40 nm) of Cs and BCP having a ratio of Cs and BCP being 1:1 are laminated in this order as the organic solid layer.

### Example 28

There was manufactured an organic solar cell according to Example 28 in a manner similar to that in Example 12 of manufacturing the organic solar cell other than a condition that CuPc (a thickness of 40 nm), CuPc and C₆₀ (co-vapor layer (a thickness of 10 nm) having a ratio of 1:1, C₆₀ (a thickness of 20 nm) and BCP (a thickness of 10 nm) are laminated in this order as the organic solid layer.

### Example 29

There was manufactured an organic solar cell according to Example 29 in a manner similar to that in Example 12 of manufacturing the organic solar cell other than a condition that CuPc (a thickness of 30 nm), CuPc and C₆₀ (co-vapor layer (a thickness of 10 nm) having a ratio of 1:1, C₆₀ (a thickness of 30 nm) and BCP (a thickness of 10 nm) are laminated in this order as the organic solid layer.

### Example 30

There was manufactured an organic solar cell according to Example 30 in a manner similar to that in Example 12 of manufacturing the organic solar cell other than a condition that CuPc (a thickness of 20 nm), CuPc and C₆₀ (co-vapor layer (a thickness of 10 nm) having a ratio of 1:1, C₆₀ (a thickness of 40 nm) and BCP (a thickness of 10 nm) are laminated in this order as the organic solid layer.

### <Cathode According to Examples 1 to 7 and Cathode According to Comparative Example 1>

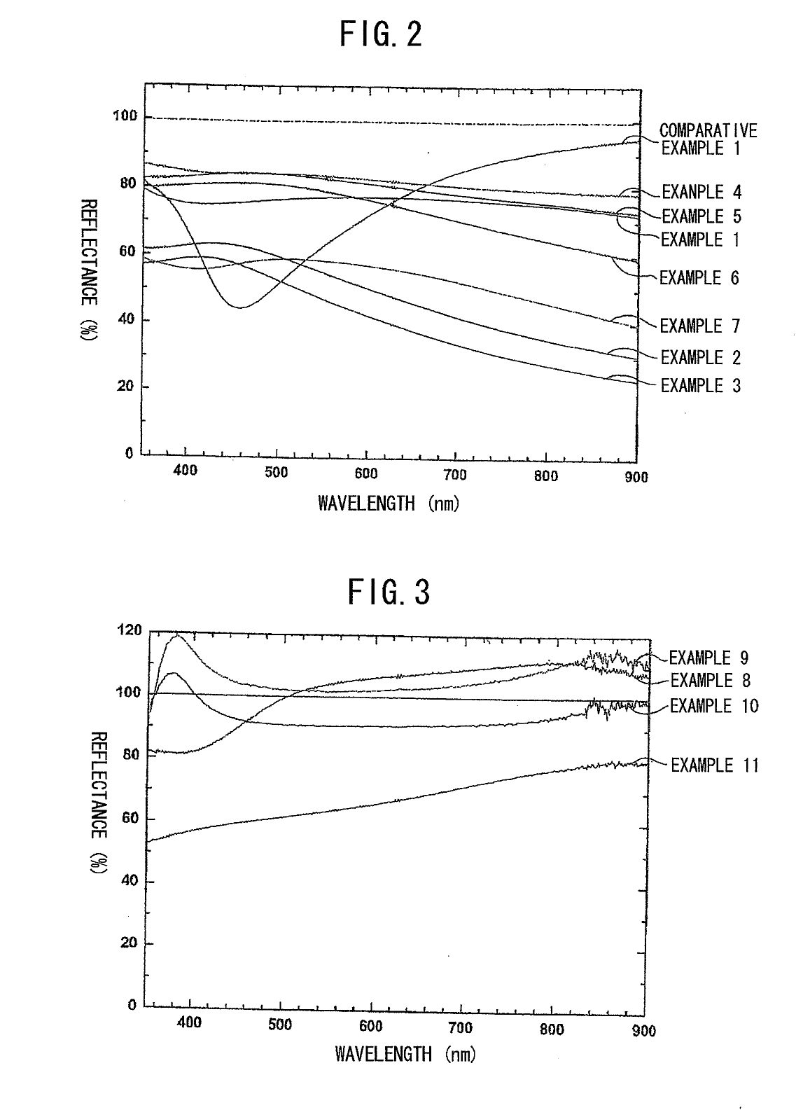

A light of a wavelength of 350 to 900 nm is introduced into the cathodes according to Examples 1 to 7 and Comparative Example 1 thereby comparing light transmittances (hereinafter referred to as “transmittance”) of the Examples and the comparative example. The result thereof is shown in FIG. 2.

(Result of Comparison Between Cathode According to Embodiment 1 and cathode according to Comparative Example 1)

As shown in FIG. 2, the cathode according to Example 1 that made from a magnesium alloy containing magnesium (Mg) and silver (Ag) formed to have a thickness of 5.0 nm shows a stabilized transmittance of about 80% in any wavelength range of wavelengths 350 to 900 nm. On the other hand, the cathode according to Comparative Example 1 that is made from silver (Ag) formed to have a thickness of 5.0 nm shows a stabilized transmittance in a range of a wavelength of 600 nm or more. However, the transmittance is unstable in a range of a wavelength of 350 to 600 nm. Accordingly, it is known that the cathode according to Example 1 of the present invention (cathode made from the alloy containing magnesium) is better than the cathode made from only silver (Ag).

### (Result of Comparison Among Examples 1 to 3)

As shown in FIG. 2, as a result of comparison among the cathode according to Example 1 that is the alloy containing magnesium made from magnesium (Mg) and silver (Ag) formed to have the thickness of 5.0 nm, the cathode according to Example 2 that is the alloy containing magnesium formed to have the thickness of 7.5 nm, and the cathode according to Example 3 that is the alloy containing magnesium formed to have the thickness of 10.0 nm, the transmittance of the cathode according to Example 1 is stabilized to be high through an entire wavelength range shown in FIG. 2. Accordingly, it is known that the thickness (5.0 nm) of the cathode according to Example 1 is most excellent.

### (Result of Comparison Among Examples 4 to 6)

As shown in FIG. 2, as a result of comparison among the cathode according to Example 6 that is formed by laminating the alloy (MgAg) (the thickness of 4.0 nm) containing magnesium on silver (Ag) (the thickness of 1.0 nm), the cathode according to Example 5 that is formed by laminating the alloy (MgAg) (the thickness of 3.0 nm) containing magnesium on silver (Ag) (the thickness of 0.7 nm), and the cathode according to Example 4 that is formed by laminating the alloy (MgAg) (the thickness of 2.0 nm) containing magnesium on silver (Ag) (the thickness of 0.5 nm), the transmittance of the cathode according to Example 4 is stabilized to be high through an entire wavelength range shown in FIG. 2. Accordingly, it is known that in case of the cathode formed by laminating the alloy (MgAg) containing magnesium, the thickness (5.0 nm) of silver (Ag) and the thickness (2.0 nm) of the alloy containing magnesium (MgAg) are most excellent.

### (Result of Comparison Among Cathode According to Examples 1 to 7 and Cathode According to Comparative Example 1)

As shown in FIG. 2, as a result of comparison among the cathodes according to Examples 1 to 7 and the cathode according to Comparative Example 1, the transmittances of the cathodes according to Examples 4 and 5 that are formed by laminating the alloy containing magnesium (Mg) and sliver (Ag) on the silver (Ag) has a higher transmittance than that of the transmittance of the cathode according to Example 1 that is made from only the alloy containing magnesium. Accordingly, it is known that a case of using the thickness (0.5 nm) of silver (Ag) and the thickness (2.0 nm) of the alloy containing magnesium (MgAg) are most excellent.

### <As to Anode According to Examples 8 to 11>

A light of a wavelength of 350 nm to 900 nm is introduced onto the cathodes according to Examples 8 to 11, and reflectances of the lights are compared with respect to Examples 8 to 11. The result is shown in FIG. 3.

As a result of comparison among the reflectances of the anodes according to the Examples, the reflectance of the anode according to Example 8 is relatively high through the entire wavelengths. Accordingly, it is known the anode made from the magnesium alloy containing magnesium (Mg) and silver (Ag) is most excellent.

### <As to Organic Solar Cell According to Examples 12 to 14>

A light of quasi sunlight is introduced into the organic solar cells according to Examples 12 to 14 thereby comparing photoelectric transfer efficiencies of the organic solar cells according to the Examples. The result is shown in Table 1.

TABLE 1

| | PHOTOELECTRIC TRANSFER EFFICIENCY (%) |
|---|---|
| Example 12 | 1.05 |
| Example 13 | 0.97 |
| Example 14 | 0.42 |

As clearly known from Table 1, when photoelectric transfer efficiencies in the solar cells according to the Examples are compared, the photoelectric transfer efficiency in the organic solar cell according to Example 12 shows the highest result. Accordingly, in consideration of the photoelectric transfer efficiency of the organic solar cell, it is known that the cathode formed by laminating the alloy (MgAg) containing magnesium (the thickness of 4.0 nm) is most excellent.

### <As to Organic Solar Cell According to Examples 12 and 15>

A light of quasi sunlight is introduced into the organic solar cells according to Examples 12 and 15 thereby comparing photoelectric transfer efficiencies of the organic solar cells according to the Examples. The result is shown in Table 2.

TABLE 2

| | PHOTOELECTRIC TRANSFER EFFICIENCY (%) |
|---|---|
| Example 12 | 1.05 |
| Example 15 | 1.46 |

As clearly known from Table 2, when photoelectric transfer efficiencies in the solar cells according to the Examples are compared, the photoelectric transfer efficiency in the organic solar cell according to Example 15 shows the highest result. Accordingly, it is known that the anode made from the magnesium alloy containing magnesium (Mg) and silver (Ag) is most excellent.

### <As to Organic Solar Cell According to Examples 16 to 23>

Alight of quasi sunlight is introduced into the organic solar cells according to Examples 16 to 23 thereby comparing photoelectric transfer efficiencies of the organic solar cells according to the Examples. The result is shown in Table 3.

TABLE 3

| | PHOTOELECTRIC TRANSFER EFFICIENCY (%) |
|---|---|
| Example 16 | 0.00 |
| Example 17 | 0.40 |
| Example 18 | 0.72 |
| Example 19 | 0.75 |
| Example 20 | 0.83 |
| Example 21 | 1.05 |
| Example 22 | 1.02 |
| Example 23 | 0.83 |

As clearly known from Table 3, when photoelectric transfer efficiencies in the solar cells according to the Examples are compared, the photoelectric transfer efficiency increases as a thickness of MoNₓ, i.e. the buffer layer used in the organic solar cells according to Examples 16 to 23 becomes thicker. However, the photoelectric transfer efficiency is gradually lowered when the thickness becomes 5.50 nm or less. Accordingly, it is known that the case where the thickness of MoNₓ, i.e. the buffer layer is 5.50 nm or less is most excellent.

### <As to Organic Solar Cell According to Examples 15 and 24>

A light of quasi sunlight is introduced into the organic solar cells according to Examples 15 and 24 thereby comparing photoelectric transfer efficiencies of the organic solar cells according to the Examples. The result is shown in Table 4.

TABLE 4

| | PHOTOELECTRIC TRANSFER EFFICIENCY (%) |
|---|---|
| Example 15 | 1.46 |
| Example 24 | 1.22 |

As clearly known from Table 4, when photoelectric transfer efficiencies in the solar cells according to the Examples are compared, the photoelectric transfer efficiency becomes high when BCP is used as the organic solid layer of the organic solar cell. Accordingly, it is known that the case where BCP is used as the organic solid layer is most excellent.

### <As to Organic Solar Cell According to Examples 24 to 27>

A light of quasi sunlight is introduced into the organic solar cells according to Examples 24 and 27 thereby comparing photoelectric transfer efficiencies of the organic solar cells according to the Examples. The result is shown in Table 5.

TABLE 5

| | PHOTOELECTRIC TRANSFER EFFICIENCY (%) |
|---|---|
| Example 24 | 1.221 |
| Example 25 | 0.079 |
| Example 26 | 0.112 |
| Example 27 | 0.003 |

As clearly known from Table 5, when photoelectric transfer efficiencies in the organic solar cells according to the Examples are compared, the photoelectric transfer efficiency becomes most high in the organic solar cell according to Example 24. Accordingly, it is known that the case where the thickness of BCP as the organic solid layer is 10 nm is most excellent.

### <As to Organic Solar Cell According to Examples 28 to 30>

A light of quasi sunlight is introduced into the organic solar cells according to Examples 28 to 30 thereby comparing photoelectric transfer efficiencies of the organic solar cells according to the Examples. The result is shown in Table 6.

TABLE 6

| | PHOTOELECTRIC TRANSFER EFFICIENCY (%) |
|---|---|
| Example 28 | 1.35 |
| Example 29 | 1.17 |
| Example 30 | 0.41 |

As clearly known from Table 6, when photoelectric transfer efficiencies in the organic solar cells according to the Examples are compared, the photoelectric transfer efficiency becomes most high in the organic solar cell according to Example 28. Accordingly, it is known that the case where the thickness of CuPc and the thickness of C₆₀ are respectively 40 nm and 20 nm is most excellent.

1. An organic solar cell comprising:
a substrate;
a first electrode;
an organic solid layer; and
a second electrode, laminated in this order, and
a buffer layer,
wherein the first electrode is one of a cathode and an anode, and the second cathode is another one of the cathode and the anode,
the second electrode is made from an alloy containing magnesium and has a thickness of 1 to 20 nm, and
the buffer layer is made from MoOₓ and positioned to be in contact with the anode.

2. An organic solar cell comprising:
a substrate;
a first electrode;
an organic solid layer; and
a second electrode, laminated in this order, and
a buffer layer,
wherein the first electrode is one of a cathode and an anode, and the second cathode is another one of the cathode and the anode,
the second electrode is formed by a plurality of layers,
at least one of the plurality of layers is made from an alloy containing magnesium,
a total thickness of the second electrode is 1 to 20 nm.
The buffer layer is made from MoOₓ and positioned to be in contact with the anode.

3. The organic solar cell according to claim 2,
wherein the second electrode formed by the plurality of layers contains a layer made from Ag.

4. The organic solar cell according to any one of claims 1 to 3,
wherein the alloy containing magnesium is an alloy made from magnesium and silver.

5. The organic solar cell according to any one of claims claim 1 to 3,
wherein the substrate is formed by laminating Si or Si and SiO₂.

6. (canceled)

7. (canceled)

8. (canceled)

9. The organic solar cell according to any one of claims 1 to 3, further comprising:
an auxiliary electrode laminated so as to be in contact with the cathode.

10. The organic solar cell according to claim 9,
wherein the auxiliary electrode is shaped like a grid or a line.
